(19) United States
(12) Patent Application Publication
(10) Pub. No.: US 2013/0026323 A1
(43) Pub. Date: Jan. 31, 2013

(54) FIXING APPARATUS FOR HARD DISK DRIVE

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/227,486

(22) Filed: Sep. 8, 2011

(30) Foreign Application Priority Data
Jul. 27, 2011 (CN) 201110211769.4

(51) Int. Cl. H05K 7/00

(52) U.S. Cl. 248/309.1

(57) ABSTRACT

A fixing apparatus for fixing a hard disk drive includes two opposite fixing arms, a handle, and two resilient fixing members. The fixing arms have substantially C-shaped cross-sections and are capable of sandwiching opposite sides of the hard disk drive, respectively. The handle is connected between first ends of the fixing arms. A stop plate protrudes inwards from an inner side of each fixing arm adjacent to the handle, to engage with a first end of the hard disk drive. The resilient fixing members are respectively fixed to the inner sides of the fixing arms, with a section of each fixing member exposed out of a second end of the corresponding fixing arm away from the handle. A fixing portion protrudes inwards from the exposed section of each fixing member, to engage with a second end of the hard disk drive away from the handle.

### BACKGROUND

1. Technical Field

The present disclosure relates to an apparatus for fixing a hard disk drive.

2. Description of Related Art

An electronic device, such as a computer, generally includes a frame, and a plurality of screws extending through the frame to fix a hard disk drive. However, these screws are usually small and difficult to handle, and the installation of the hard disk drive in the computer is labor-intensive.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a fixing apparatus.

FIG. 2 is an assembled, isometric view of FIG. 1, together with a hard disk drive.

FIG. 3 is an assembled, isometric view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

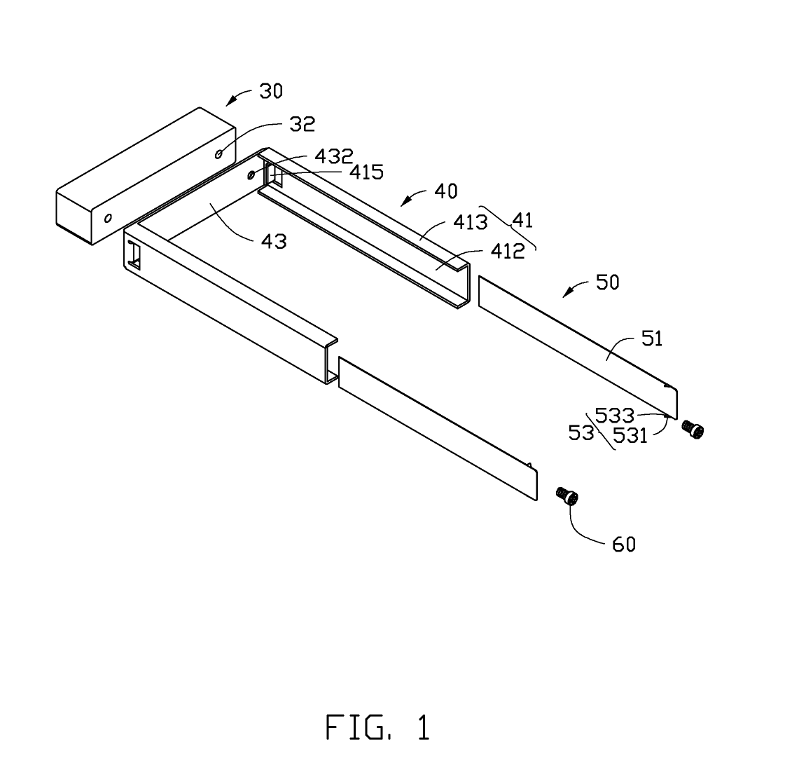

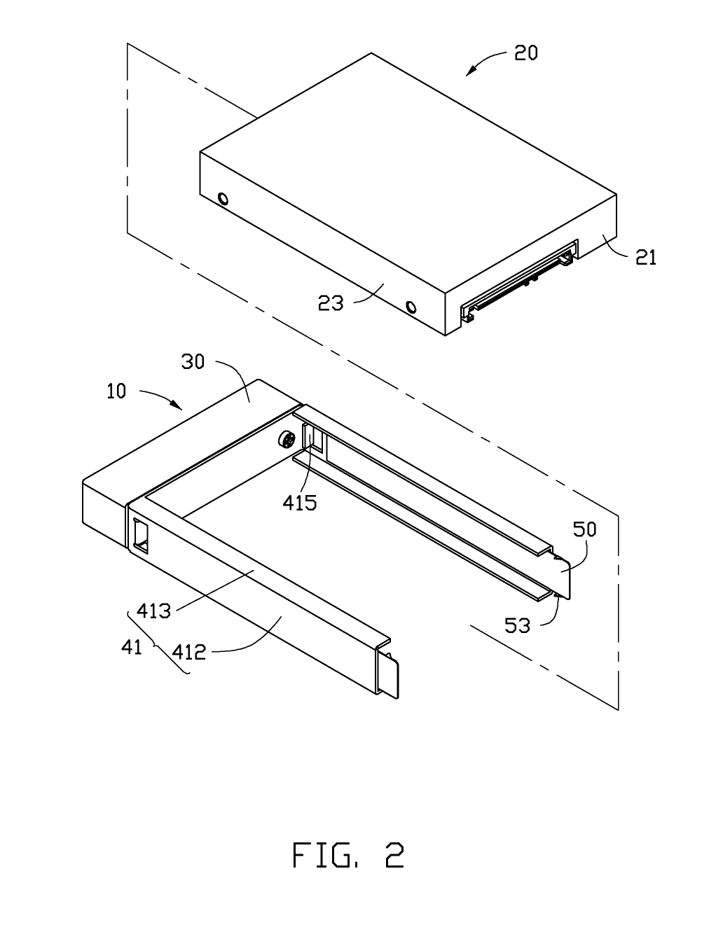

Referring to FIGS. 1 and 2, an exemplary embodiment of a fixing apparatus 10 is provided to fix a hard disk drive 20. The hard disk drive 20 includes two opposite end walls 21, and two opposite sidewalls 23 connected between the end walls 21. The fixing apparatus 10 includes a handle 30, a frame 40, and two fixing members 50.

Two fixing holes 32 are defined in a side of the handle 30, respectively adjacent to opposite ends of the handle 30.

The frame 40 includes two opposite fixing arms 41 each having a substantially C-shaped cross-section, and a connecting plate 43 perpendicularly connected between the first ends of the fixing arms 41. Two through holes 432 are defined in the connecting plate 43, respectively adjacent to the fixing arms 41. Each fixing arm 41 includes a side plate 412, and two flanges 413 perpendicularly extending inwards from the top and the bottom of the side plate 412, respectively. A stop plate 415 extends inwards from each side plate 412 adjacent to the connecting plate 43.

Each fixing member 50 includes a rectangular resilient plate 51. Two fixing portions 53 are respectively formed on the top and the bottom of a distal end of the resilient plate 51. Each fixing portion 53 includes a slanted surface 531 facing the distal end, and a latching surface 533 perpendicular to the resilient plate 51 and facing away from the distal end.

To assemble the fixing apparatus 10, the fixing members 50 are respectively fixed to inner surfaces of the side plates 412, with sections of the resilient plates 51 having the fixing portions 53 exposed out of second ends of the corresponding fixing arms 41 away from the stop plates 415. The fixing portions 53 are spaced from the second ends of the corresponding fixing arms 41. Two screws 60 are respectively extended through the through holes 432 of the connecting plate 43, and engage in the corresponding fixing holes 32 of the handle 30, to fix the frame 40 to the handle 30. In the embodiment, the frame 40 and the fixing members 50 are made of stainless steel, the fixing members 50 are respectively fixed to the fixing arms 41 of the frame 40 by welding.

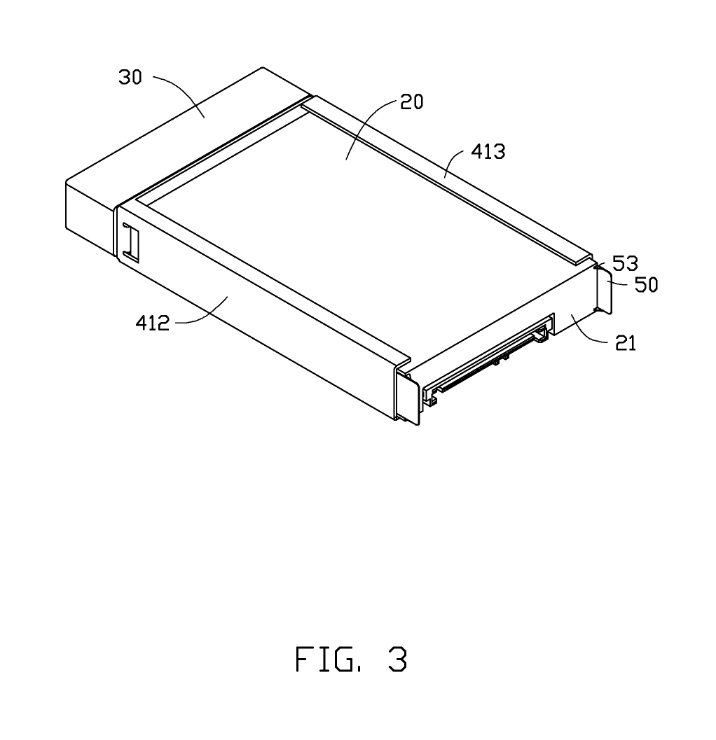

Referring to FIG. 3, to assemble the hard disk drive 20 to the fixing apparatus 10, the sidewalls 23 of the hard disk drive 20 are aligned with the second ends of the fixing arms 41, respectively. The hard disk drive 20 is moved towards the handle 30, and pushes the slanted surfaces 531 of the fixing portions 53, to outwardly deform the sections of the resilient plates 51 exposed out of the corresponding fixing arms 41. The sidewalls 23 of the hard disk drive 20 pass over the corresponding fixing portions 53 and engage with inner surfaces of the corresponding resilient plates 51 received in the fixing arms 41. The bottom surface of the hard disk drive 20 is supported on the flanges 413 at the bottoms of the fixing arms 41, and the top surface of the hard disk drive 20 engages with inner sides of the flanges 413 at the tops of the fixing arms 41. When a first end wall 21 of the hard disk drive 20 engages with the stop plates 415, the sections of the resilient plates 51 exposed out of the corresponding fixing arms 41 are restored, to allow the latching surfaces 533 of the fixing portions 53 to engage with a second end wall 21 of the hard disk drive 20 opposite to the first end wall 21. Opposite portions of the hard disk drive 20 adjacent to the sidewalls 23 are sandwiched by the corresponding fixing arms 41, thereby, the hard disk drive 20 is fixed to the fixing apparatus 10.

To detach the hard disk drive 20 from the fixing apparatus 10, the sections of the resilient plates 51 exposed out of the corresponding fixing arms 41 are deformed outwards, to allow the fixing portions 53 to disengage from the second end wall 21 of the hard disk drive 20. Therefore, the hard disk drive 20 can be pulled away from the handle 30 and detached from the fixing apparatus 10.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fixing apparatus for fixing a hard disk drive comprising two opposite sidewalls and two opposite end walls connected between the sidewalls, the fixing apparatus comprising:
two opposite fixing arms with substantially C-shaped cross-sections for respectively sandwiching opposite portions of the hard disk drive respectively adjacent to the sidewalls;
a handle connected between first ends of the fixing arms, a stop plate protruding inwards from an inner side of each fixing arm adjacent to the handle, to engage with one of the end walls of the hard disk drive; and
two resilient fixing members respectively fixed to the inner sides of the fixing arms, wherein a section of each fixing member is exposed out of a second end of the corresponding fixing arm away from the handle, at least one fixing portion protrudes inwards from the exposed section of each fixing member, to engage with the other end wall of the hard disk drive.

2. The fixing apparatus of claim 1, wherein each of the fixing arms comprises a side plate to engage with a corresponding one of the sidewalls of the hard disk drive, and two flanges extending inwards from the top and the bottom of the side plate to engage with top and bottom surfaces of the hard disk drive, respectively.

3. The fixing apparatus of claim 2, wherein the stop plates extend inwards from inner surfaces of the side plates of the fixing arms, respectively.

4. The fixing apparatus of claim 2, wherein the fixing members are respectively fixed to the inner surfaces of the side plates of the fixing arms.

5. The fixing apparatus of claim 4, wherein the fixing members and the fixing arms are made of stainless steel, the fixing members are respectively fixed to the fixing arms by welding.

6. The fixing apparatus of claim 1, wherein each fixing member comprises a resilient plate fixed to the inner side of the corresponding fixing arm, each fixing portion comprises a latching surface facing the handle and perpendicular to the resilient plate to engage with said other end wall of the hard disk drive, and a slanted surface facing away from the handle.

7. The fixing apparatus of claim 1, wherein a connecting plate is connected between the first ends of the fixing arms, two through holes are defined in the connecting plate, two fixing holes are defined in a side of the handle, two screws are respectively extended through the through holes of the connecting plate, and engage in the corresponding fixing holes of the handle, to fix the fixing arms to the handle.
